(19) United States
(12) Patent Application Publication
(10) Pub. No.: US 2025/0112111 A1
(43) Pub. Date: Apr. 3, 2025

(54) FAN-OUT PANEL LEVEL PACKAGING STRUCTURE AND MANUFACTURING METHOD

(71) Applicant: Zhuhai ACCESS Semiconductor Co., Ltd, Guangdong (CN)

(72) Inventors: XIANMING CHEN, Guangdong (CN); YEJIE HONG, Guangdong (CN); BENXIA HUANG, Guangdong (CN)

(21) Appl. No.: 18/889,960

(22) Filed: Sep. 19, 2024

(30) Foreign Application Priority Data
Sep. 28, 2023 (CN) 2023112820782

(51) Int. Cl. H01L 23/367; H01L 21/48; H01L 23/00; H01L 23/31; H01L 23/373

(52) U.S. Cl. CPC H01L 23/3675; H01L 21/4882; H01L 24/19; H01L 24/20; H01L 23/3107; H01L 23/3736; H01L 2224/19; H01L 2224/2101; H01L 2224/221

(57) ABSTRACT

A method for manufacturing a fan-out panel level packaging structure includes preparing a panel level frame having a first dielectric layer and a through-cavity surrounded by the first dielectric layer, wherein the frame includes first and second surfaces, and a heat dissipation copper post extending through the first dielectric layer and exposed to the first surface, mounting a device in the through-cavity with a terminal face of the device flush with the second surface and the terminal face including a first terminal and a second terminal; forming a second dielectric layer overlying the device on the first surface, forming a first rewiring layer on the second surface, and forming a third dielectric layer on the first rewiring layer, and forming a second rewiring layer on the third dielectric layer. The second rewiring layer may be in conductive connection with the first rewiring layer.

### CROSS-REFERENCE TO RELATED APPLICATION AND CLAIM OF PRIORITY

This application claims the benefit under 35 USC § 119 of Chinese Patent Application No. 2023112820782, Sep. 28, 2023, in the China Intellectual Property Office, the entire disclosure of which is incorporated herein by reference for all purposes.

### BACKGROUND

### 1. TECHNICAL FIELD

The present disclosure relates to the technical field of electronic devices, particularly to a fan-out panel level packaging structure and a manufacturing method.

### 2. BACKGROUND ART

With the development of electronic information technology, multi-functionality and miniaturization are the main drivers of update and iteration of electronic products. In order to realize the versatility of electronic products, the design of integrated circuits and packaging modules for key components is more and more complicated. In order to realize the portability of electronic products, the size and thickness of electronic products are required to be smaller and smaller. In view of this, high-density integration is an important trend for future semiconductor packaging, and fan-out packaging technology is currently a very important advanced packaging technology.

The fan-out packaging technology currently used in more mature applications is fan-out wafer level package (FOWLP), which has package sizes of mostly 6 inches and 8 inches. Although the size of silicon wafers is increasing, the expensive material groups and manufacturing processes still limit the diameter size to 12 inches, which also limits the quantity of fan-out units that can be placed on the wafer. Despite the widespread interest in 18 inch wafers, the required investments, material groups and associated equipment remain unknown. In addition, the unit cost of FOWLP increases due to the limited quantity of chip support structures processed simultaneously, which is prohibitively expensive for markets that require highly competitive pricing, such as the wireless communications, home appliances, and automotive markets.

Therefore, it is necessary to propose a fan-out panel level package (FOPLP) scheme, which uses panel level packaging substrate to realize chip packaging and fan-out, so as to improve packaging efficiency and reduce processing costs. However, in general panel level package substrates, it is difficult to achieve fan-out of highly dense I/O chips due to the lack of an effective heat dissipation solution for the panel caused by the use of polymer-based substrates and due to the lack of multilayer process capability of FOPLP comparable to that of FOWLP.

### SUMMARY

In view of this, the purpose of this disclosure is to propose a panel level fan-out packaging structure and a manufacturing method.

On the basis of the above-mentioned object, in a first aspect, the present disclosure provides a manufacturing method of a fan-out panel level packaging structure, characterized by including:
(a) preparing a panel level frame having a first dielectric layer and a through-cavity surrounded by the first dielectric layer, wherein the frame includes a first surface and a second surface, and a heat dissipation copper post extending through the first dielectric layer and exposed to the first surface;
(b) mounting a device in the through-cavity with a terminal face of the device flush with the second surface and the terminal face including a first terminal and a second terminal; forming a second dielectric layer, which covers the device, on the first surface;
(c) forming a first rewiring layer, which fans out the first terminal, on the second surface; and
(d) forming a third dielectric layer on the first rewiring layer, and forming a second rewiring layer, which fans out the second terminal, on the third dielectric layer, wherein the second rewiring layer is in conductive connection with the first rewiring layer.

In some implementations, the manufacturing method further includes:
(f) windowing the second dielectric layer to expose the heat dissipation copper post and a back surface of the device; and
(g) forming a fourth rewiring layer including a heat dissipation copper surface on the second dielectric layer, wherein the heat dissipation copper surface is in conductive connection with the heat dissipation copper post and the back surface of the device.

In some implementations, the frame further includes a conductive copper post, two end faces of the conductive copper post being exposed to the first surface and the second surface, respectively,
wherein the manufacturing method further includes:
(f) windowing the second dielectric layer to expose the conductive copper post, the heat dissipation copper post and a back surface of the device; and
(g) fabricating a fourth rewiring layer including a functional loop terminal and a heat dissipation copper surface on the second dielectric layer, wherein the functional loop terminal is in conductive connection with the conductive copper post and the heat dissipation copper surface is in conductive connection with the heat dissipation copper post and the back surface of the device.

In some implementations, the conductive copper post is further in conductive connection with the functional loop terminal and the first rewiring layer.

In some implementations, step (a) includes sub-steps of:
(a1) preparing a panel level carrier plate, and forming the heat dissipation copper post and an annular sacrificial copper post on the carrier plate, wherein a height of the heat dissipation copper post is less than a height of the sacrificial copper post;
(a2) forming the first dielectric layer on the carrier plate so that the sacrificial copper post is exposed to the first dielectric layer;
(a3) removing the carrier plate; and
(a4) etching and removing the sacrificial copper post so that the first dielectric layer surrounded by the sacrificial copper post falls off to form the frame having the heat dissipation copper post and the through-cavity, wherein the frame includes the first surface and the second surface, and the heat dissipation copper post is exposed to the first surface.

In some implementations, step (a) includes sub-steps of:
(a1) preparing a panel level carrier plate, and forming the conductive copper post, the heat dissipation copper post and an annular sacrificial copper post on the carrier plate, wherein a height of the heat dissipation copper post is less than a height of the sacrificial copper post and the conductive copper post;
(a2) forming the first dielectric layer on the carrier plate so that the sacrificial copper post is exposed to the first dielectric layer;
(a3) removing the carrier plate; and
(a4) etching and removing the sacrificial copper post so that the first dielectric layer surrounded by the sacrificial copper post falls off to form the frame having the conductive copper post, the heat dissipation copper post and the through-cavity, wherein the frame includes the first surface and the second surface, the heat dissipation copper post is exposed to the first surface, and the conductive copper post is exposed to the first surface and the second surface.

In some implementations, a height difference between the heat dissipation copper post and the sacrificial copper post is 20-50 μm.

In some implementations, the sacrificial copper post and the conductive copper post are flush with the second surface.

In some implementations, step (d) includes sub-steps of:
(d1) windowing the third dielectric layer by means of exposure and development to expose the second terminal of the device and the first rewiring layer;
(d2) forming a third metal seed layer on a surface of the third dielectric layer;
(d3) applying a third photoresist layer on the third metal seed layer, and patterning the third photoresist layer to form a third feature pattern;
(d4) electroplating the third feature pattern to form a second rewiring layer fanning out the second terminal and being in conductive connection with the first rewiring layer; and
(d5) removing the third photoresist layer and etching the exposed third metal seed layer.

In some implementations, the manufacturing method further includes:
(e) forming a fourth dielectric layer on the second rewiring layer, and fabricating a third rewiring layer on the fourth dielectric layer, wherein the third rewiring layer is in conductive connection with the second rewiring layer.

In some implementations, the heat dissipation copper post constitutes rest of the frame except the cavity and is separated from the cavity via the first dielectric layer; and the heat dissipation copper surface covers the second surface of the frame.

In some implementations, the heat dissipation copper post constitutes rest of the frame except the cavity and the conductive copper post and is separated from the cavity and the conductive copper post via the first dielectric layer; and the heat dissipation copper surface covers the second surface except the functional loop terminal.

In a second aspect, an embodiment of the present disclosure provides a fan-out panel level packaging structure, characterized by including a frame and a device embedded in the frame, wherein the frame includes a heat dissipation copper post and a first dielectric layer for separating the heat dissipation copper post and the device, wherein the frame has a first surface and a second surface opposite to each other, and a first rewiring layer, a third dielectric layer and a second rewiring layer are successively provided on the second surface; and the first rewiring layer and the second rewiring layer are in conductive connection with and fan out a first terminal and a second terminal of the device, respectively, and the first rewiring layer is in conductive connection with the second rewiring layer.

In some implementations, the packaging structure further includes a fourth dielectric layer on the second rewiring layer and a third rewiring layer on the fourth dielectric layer, the third rewiring layer being in conductive connection with the second rewiring layer.

In some implementations, the packaging structure further includes a second dielectric layer provided on the first surface of the frame and a fourth rewiring layer on the second dielectric layer, wherein the fourth rewiring layer includes a heat dissipation copper surface, the heat dissipation copper surface is in conductive connection with the heat dissipation copper post and a back surface of the device, and the heat dissipation copper surface covers the first surface.

In some implementations, the frame further includes: a conductive copper post, the conductive copper post being separated from the heat dissipation copper post via the first dielectric layer; a second dielectric layer provided on the first surface of the frame and a fourth rewiring layer on the second dielectric layer, the fourth rewiring layer including a functional loop terminal and a heat dissipation copper surface, wherein the heat dissipation copper surface is in conductive connection with the heat dissipation copper post and a back surface of the device, the heat dissipation copper surface covers the first surface except the functional loop terminal, and two ends of the conductive copper post are respectively in conductive connection with the functional loop terminal and the first rewiring layer.

It can be seen from the foregoing contents that the embodiments of the present disclosure provide a fan-out panel level packaging structure and a manufacturing method, which achieve fan-out and epitaxy of a high-density I/O device by fanning out a plurality of terminals of a device embedded in a metal frame successively, so as to solve the problem that the existing fan-out panel level packaging process capability cannot satisfy the fan-out requirement of the high-density I/O device; at the same time, the heat dissipation problem of the high-frequency device is solved by arranging the heat dissipation copper post and the heat dissipation copper surface which are in conductive connection with the back surface of the device in a large area; in addition, by forming a height difference between the heat dissipation copper post and the conductive copper post and the sacrificial copper post, it is not necessary to grind the heat dissipation copper post after etching and removing the sacrificial copper post, thereby saving the process and significantly improving the process efficiency.

### BRIEF DESCRIPTION OF THE DRAWINGS

In order to more clearly illustrate the technical solutions of the present disclosure or related art, a brief description will be given below of the accompanying drawings which are required to be used in the description of the embodiments or relevant technology. It is obvious that the drawings in the description below are only embodiments of the present disclosure, and it would be possible for a person skilled in the art to obtain other drawings according to these drawings without involving any inventive effort.

FIGS. 1A-1K show schematic cross-sectional diagrams of intermediate structures at various steps of a manufacturing method of a fan-out panel level packaging structure provided by an embodiment of the present disclosure;

FIG. 1B is a top diagram of FIG. 1A;

FIG. 2 illustrates a schematic diagram of a fan-out panel level packaging structure provided by an embodiment of the present disclosure;

FIGS. 3A-3D show schematic cross-sectional diagrams of intermediate structures at part of the steps of another manufacturing method of a fan-out panel level packaging structure provided by an embodiment of the present disclosure; and

FIG. 4 shows a schematic diagram of another fan-out panel level packaging structure provided by an embodiment of the present disclosure.

### DETAILED DESCRIPTION OF THE EMBODIMENTS

In order to make the purpose, technical solution, and advantages of the present disclosure clearer, the following is a further detailed explanation of the present disclosure, combined with specific embodiments and referring to the accompanying drawings.

It should be noted that, unless otherwise defined, technical or scientific terms used in the embodiments of the present disclosure shall have the ordinary meaning as understood by a person skilled in the art to which the present disclosure belongs. “First”, “second”, and similar terms used in the embodiments of the present disclosure do not denote any order, quantity, or importance, but are rather used to distinguish different constituent parts. The word “include” or “comprise”, and the like, means that the elements or items preceding the word encompass the elements or items listed after the word and equivalents thereof, but do not exclude other elements or items. “Connect” or “attach” and like terms are not limited to physical or mechanical connections, but may include electrical connections, whether direct or indirect. “Up”, “down”, “left”, “right”, etc. are only used to indicate a relative positional relationship, which may change accordingly when the absolute position of the object being described changes.

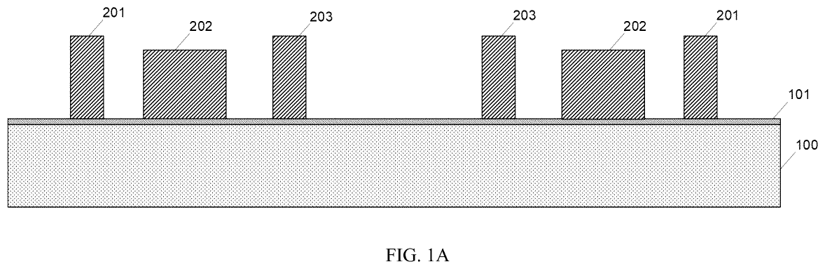

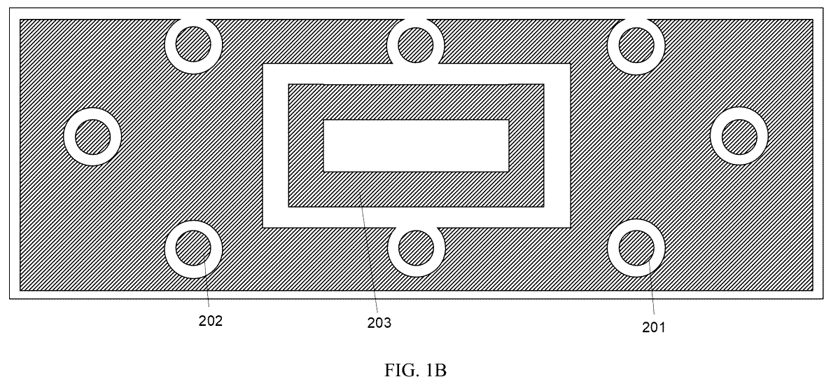

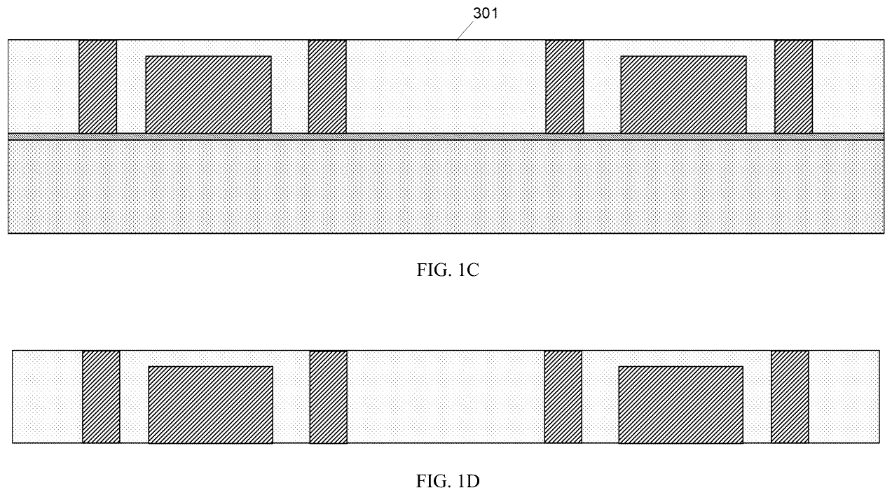

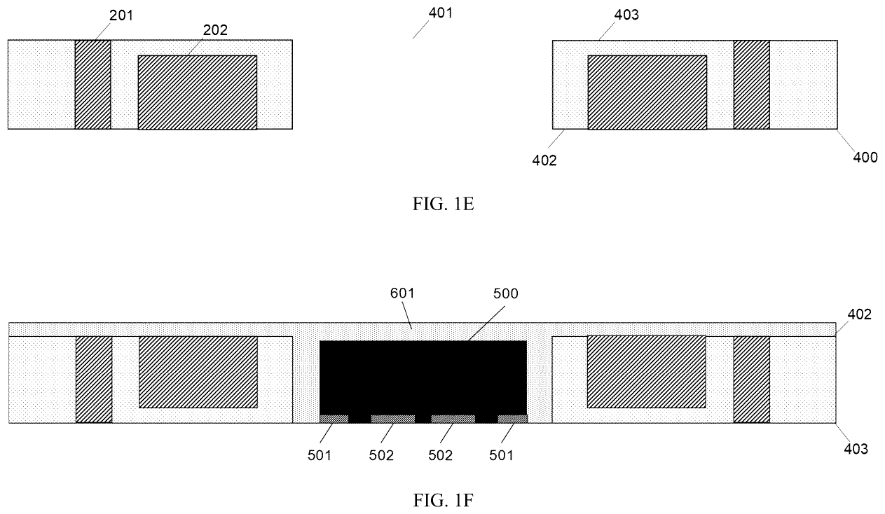

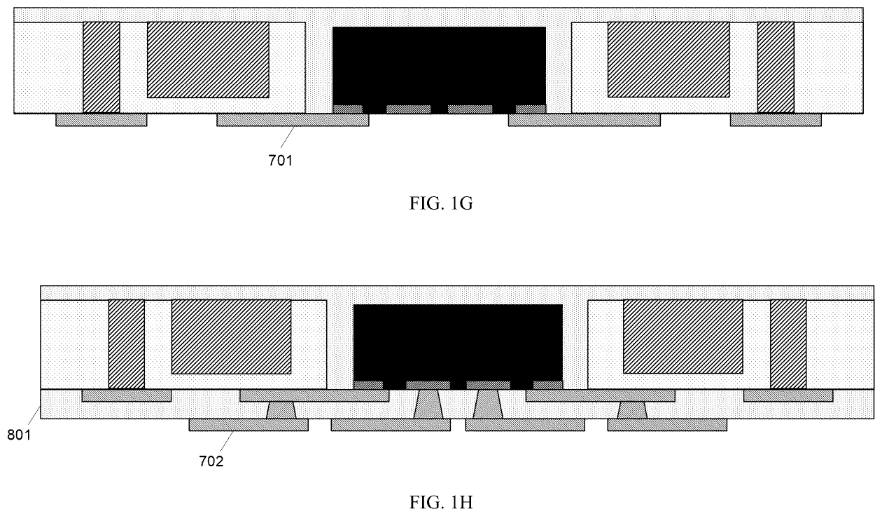

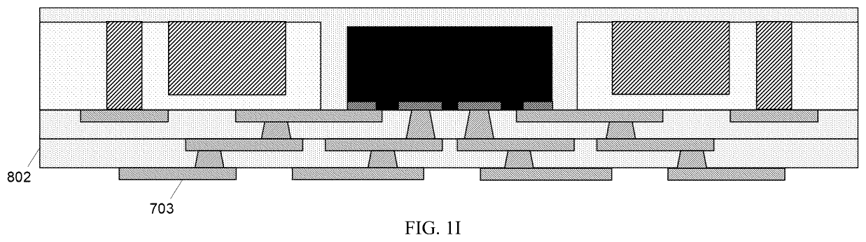

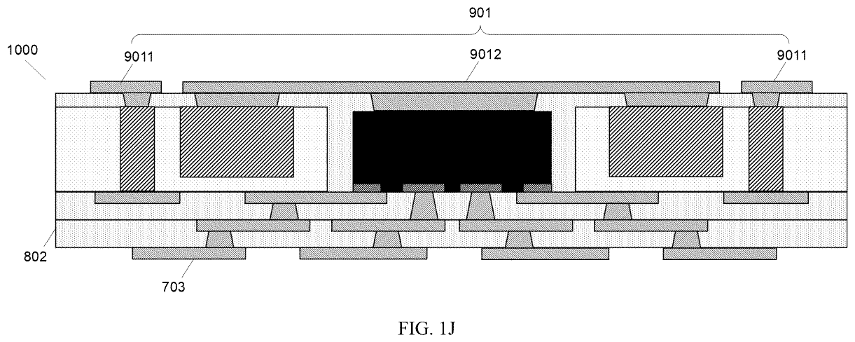

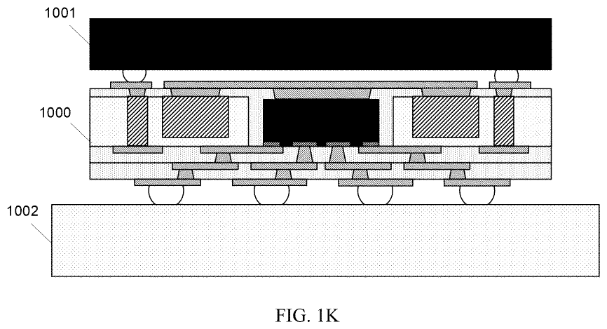

An exemplary embodiment of the present disclosure provides a manufacturing method of a fan-out panel level packaging structure. FIGS. 1A-1K show schematic cross-sectional diagrams of intermediate structures at various steps of a manufacturing method of a fan-out panel level packaging structure provided by an embodiment of the present disclosure; Specifically, the manufacturing method includes steps of:

Preparing a panel level carrier plate 100, and forming a conductive copper post 201, a heat dissipation copper post 202 and a sacrificial copper post 203 on the carrier plate 100-step (a), as shown in FIG. 1A. It shall be noted that the panel level carrier plate 100 may be circular or rectangular such as rectangular or square. The dimensions of the panel level carrier plate 100 may be selected according to actual needs, for example 300 mm×300 mm, 510 mm×515 mm, 600 mm×600 mm. Here, a first metal seed layer 101 may be formed in advance on the carrier plate 100. For example, the first metal seed layer 101 may be formed on the carrier plate 100 by means of metal sputtering. A material of the first metal seed layer 101 may be copper, titanium or a combination thereof, preferably a combination of copper and titanium.

In some embodiments, the specific steps of forming the conductive copper post 201, the heat dissipation copper post 202, and the sacrificial copper post 203 may be to first form a rewiring pattern on the first metal seed layer 101, then electroplating the rewiring pattern, and finally stripping.

Alternatively, the sacrificial copper post 203 is selected from an annular structure or a continuous cylindrical enclosure structure. FIG. 1B is a top diagram of a structure shown in FIG. 1A. FIG. 1B exemplarily shows that the sacrificial copper post 203 is of a continuous columnar fence structure. Here, a subsequent step will etch and remove the sacrificial copper post 203 such that the first dielectric layer surrounded by the sacrificial copper post 203 falls off to form a through-cavity, facilitating subsequent placement of the device in the through-cavity.

It should be noted that the quantity of sacrificial copper post(s) 203 is not limited to one, and may be defined according to the quantity of device(s) (e.g. chip(s)) to be packaged and a panel area, which is not limited by the present disclosure.

Conventional FOPLP solutions lack an effective heat dissipation solution. In view of this, the embodiment of the present disclosure is provided with the heat dissipation copper post (heat dissipation block) 202 with a large area. It should be noted that, in general, the heat dissipation copper post 202 with a large area can be maximally provided after avoiding the sacrificial copper post 203 and the conductive copper post 201, so as to improve the heat dissipation effect. It should be understood that the heat dissipation copper post 202 may not need to be prepared if the heat dissipation function is not considered.

Alternatively, a thickness (corresponding to a height) of the heat dissipation copper post 202 is controlled to be smaller than a thickness (corresponding to a height) of the conductive copper post 201 and the sacrificial copper post 203 during electroplating. As an example, the height of the heat dissipation copper post 202 may be 20-50 um less than the height of the conductive copper post 201 and the sacrificial copper post 203. Alternatively, the conductive copper post 201 and the sacrificial copper post 203 may have substantially the same height such that the conductive copper post 201 is exposed to the first surface and the second surface of the frame.

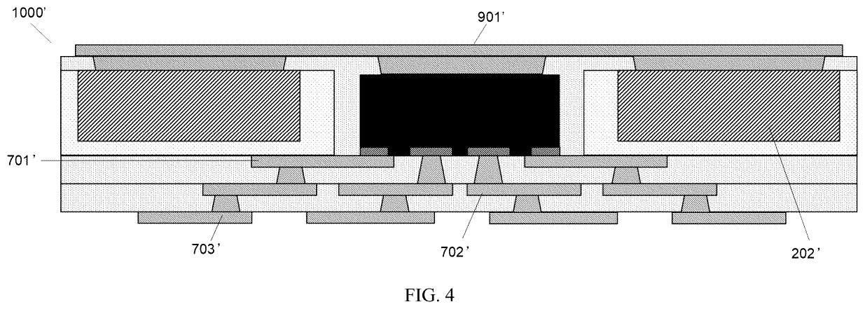

Here, the conductive copper post 201 may be used to provide conductive connection to the device 1001 when a flip chip device 1001 is packaged on a surface of the fan-out panel level packaging structure 1000 (see FIG. 1K). It should be appreciated that if the fan-out panel level packaging structure 1000 does not require the flip chip device 1001, the conductive copper post 201 (as shown in FIG. 4) may be eliminated.

Next, a first dielectric material is applied to form a first dielectric layer 301, which exposes the sacrificial copper post 203 and end faces of the conductive copper post 201-step (b), as shown in FIG. 1C. Here, since the height of the heat dissipation copper post 202 is smaller than that of the sacrificial copper post 203 and the conductive copper post 201, the heat dissipation copper post 202 remains encapsulated in the first dielectric layer 301.

In some embodiments, the first dielectric material may be applied by conventional bonding, vacuum rapid pressing, coating, etc. until the first dielectric material completely covers the conductive copper post 201, the heat dissipation copper post 202, and the sacrificial copper post 203. Next, the first dielectric material is thinned to form a first dielectric layer 301. Here, in the thinning process, a grinding plate, plasma etching and other processes can be used to expose the end faces of the sacrificial copper post 203 and the conductive copper post 201. The height of the heat dissipation copper post 202 is smaller than the height of the conductive copper post 201 and the sacrificial copper post 203, so that the heat dissipation copper post 202 does not need to be thinned by a grinding plate, and the processing efficiency is greatly improved.

Alternatively, the first dielectric material may be a polymer dielectric material containing glass fibers to help ensure the strength and rigidity of the substrate. Illustratively, the polymer medium including the glass fiber may be one selected from the group consisting of liquid crystal polymer, BT (bismaleimide triazine) resin, prepreg, ABF (Ajinomoto build-up) film, epoxy, and polyimide resin, but the present disclosure is not limited thereto.

The carrier plate is then removed-step (c), as shown in FIG. 1D. Here, removing the carrier plate includes removing the carrier plate 100 and etching the exposed metal seed layer 101.

Next, the sacrificial copper post 203 is etched and removed, causing the dielectric material surrounded by sacrificial copper post 203 to fall off, forming a frame 400 having conductive copper post 201, the heat dissipation copper post 202, and the through-cavity 401-step (d), as shown in FIG. 1E.

In some implementations, the frame 400 includes a first surface 402 and a second surface 403, with the heat dissipation copper post 202 exposed to the first surface 402 and not exposed to the second surface 403.

With regard to the specific manner of etching and removing the sacrificial copper post 203, the present disclosure is exemplified as follows: a first photoresist layer is first applied to prepare a first feature pattern of the sacrificial copper post 203, followed by etching, and after the sacrificial copper post 203 is etched and removed, the photoresist is stripped away to obtain the frame 400 as shown in FIG. 1E.

Then, the device 500 is mounted in the through-cavity with the terminal face of the device flush with the second surface 403. A second dielectric material is applied to the first surface 402 to package the device 500 to form a second dielectric layer 601-step (e), as shown in FIG. 1F.

The device 500 may be an IC chip, a logic circuit element, a power amplifier, a capacitor, an inductor, a resistor, etc. and the present disclosure is not limited in this respect. The terminal face of the device 500 includes at least a first terminal 501 and a second terminal 502.

In some embodiments, a bonding medium layer may be formed on the second surface 403, the bonding medium layer having a viscosity at normal temperature or under heating to bond components; the adhesive medium layer may be formed by pressing a medium material having a shape covering function in a dry film type. The device 500 is then placed in the through-cavity and attached to the bonding medium layer. Whether heating is performed is decided based on the amount of adhesion of the bonding medium layer. For example, the device may be heated when the adhesion is low. The bonding medium layer may be removed after the second dielectric layer 601 is formed.

Alternatively, the second dielectric material may be the same as or different from the first dielectric material.

Next, a first rewiring layer 701 is formed on the second surface 403, and the first terminal 51 of the device 500 is fanned out-step (f), as shown in FIG. 1G.

In some embodiments, the step of fabricating the first rewiring layer 701 may include: first forming a second metal seed layer on the second surface 403; then, applying a second photoresist layer on the second metal seed layer, and patterning the second photoresist layer to form a second feature pattern; then electroplating the second feature pattern to form a first rewiring layer fanning out the first terminal; finally, removing the second photoresist layer and etching the exposed second metal seed layer. Here, the material of the second metal seed layer is similar to that of the first metal seed layer and will not be described in detail. Alternatively, the material of the first rewiring layer may be copper.

Then, a third dielectric material is applied on the first rewiring layer to form a third dielectric layer 801, a second rewiring layer 702 is fabricated on the third dielectric layer, and the second rewiring layer 702 fans out the second terminal 502 of the device and connects the first rewiring layer 701-step (g), as shown in FIG. 1H. It should be noted that the second rewiring layer 702 may simultaneously function as an epitaxial first rewiring layer.

In some embodiments, the third dielectric material may be a photosensitive dielectric material with a high resolution capability to facilitate subsequent windowing of tiny through holes.

In some embodiments, a third dielectric material is applied over the first rewiring layer by a process such as bonding, coating, etc., and then the third dielectric material is partially removed by exposure and development to expose the second terminal of the device and parts of the first rewiring layer, and finally cured to form the third dielectric layer 801.

In some embodiments, the step of fabricating the second rewiring layer 702 may include: forming a third metal seed layer on the surface of the third dielectric layer 801; applying a third photoresist layer on the third metal seed layer, and patterning the third photoresist layer to form a third feature pattern; electroplating the third feature pattern to form a second rewiring layer which fans out the second terminal and is connected to the first rewiring layer; and the third photoresist layer is removed and the exposed third metal seed layer is etched.

It can be seen therefrom that the technical solution of the embodiments of the present disclosure can achieve reasonable wiring for fan-out of high-density I/O devices by using the graded fan-out technology of device terminals. The horizontal rewiring space is effectively reduced to solve the technical problem that it is difficult for the existing FOPLP to achieve fan-out of the high-density I/O device.

Next, a fourth dielectric material may be applied on the second rewiring layer 702 to form a fourth dielectric layer 802, and a third rewiring layer 703 is fabricated on the fourth dielectric layer 802, the third rewiring layer 703 connecting the second rewiring layer 702-step (h), as shown in FIG. 1I. It is noted that the third rewiring layer 703 may be epitaxial from the second rewiring layer 702.

The fabricating process of the fourth dielectric layer 802 and the third rewiring layer 703 is described with reference to the third dielectric layer 801 and the second rewiring layer 702, and will not be described again.

Then, the second dielectric layer 601 (namely, an packaging layer of the device 500) is windowed to expose the conductive copper post 201, the heat dissipation copper post 203 and the back surface of the device 500, and a fourth rewiring layer 901 including a functional loop terminal 9011 and a heat dissipation copper surface 9012 is fabricated on the windowed second dielectric layer 601 to obtain a device fan-out packaging structure 1000-step (i), as shown in FIG. 1J. It is noted that the heat dissipation copper surface 9012 is connected to the heat dissipation copper post 202 and the back side of the device 500, and the functional loop terminal 9011 is connected to the conductive copper post 201. The heat dissipation copper surface 9012 may cover substantially the entire first surface of the frame, with only the functional loop terminal 9011 exposed in the presence of the conductive copper post 201. The heat dissipation copper post 203 of a large area and the heat dissipation copper surface 9012 help to realize the large-area direct heat dissipation and significantly improve the heat dissipation capacity of the packaging structure 1000.

Regarding the fabricating process of the fourth rewiring layer 901, reference may be made to the third rewiring layer, which will not be described again.

Finally, the functional loop terminal 9011 can be used as an upper pad to realize an upper package, so as to realize a conductive connection with another device or a package body 1001, and the third rewiring layer 703 can also form a lower pad to realize a conductive connection with a substrate or a PCB board 1002-step (j), as shown in FIG. 1K. It is noted that another device 1001 may be an IC chip.

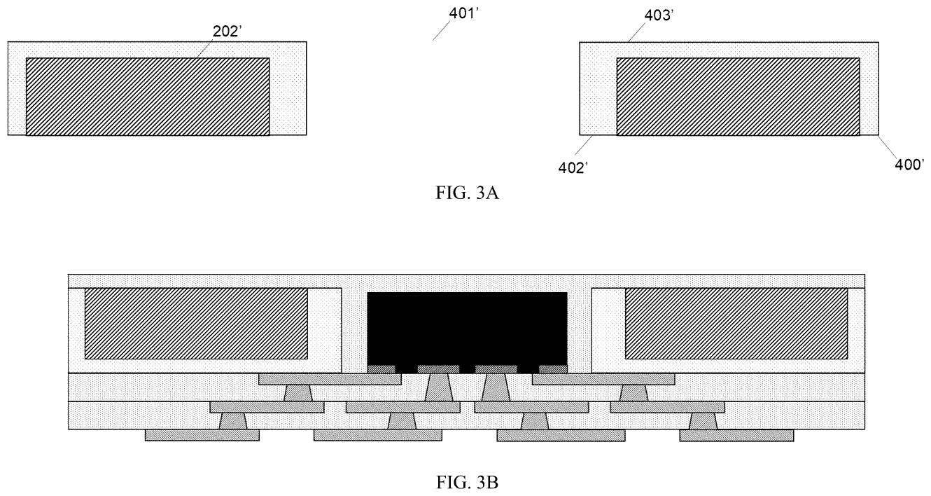

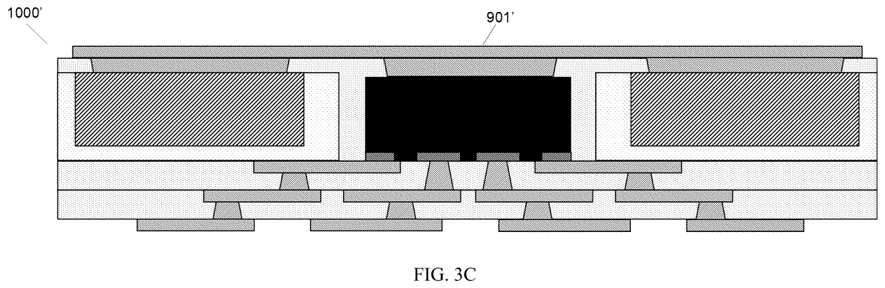

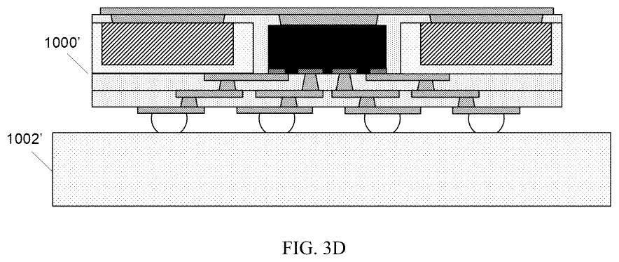

An exemplary embodiment of the present disclosure provides another manufacturing method of a fan-out panel level packaging structure. FIGS. 3A-3D show schematic cross-sectional diagrams of intermediate structures at part of the steps of another manufacturing method of a fan-out panel level packaging structure provided by an embodiment of the present disclosure. The difference between the packaging structures prepared in FIGS. 3A-3D and those in FIGS. 1A-1K is that no conductive copper post 201 is included. Specifically, the manufacturing method includes steps of:

A frame 400′ with a heat dissipation copper post 202′ and a through-cavity 401′ is prepared-step (a′), as shown in FIG. 3A. It is noted that regarding the specific process of step (a′), reference may be made to the aforementioned steps (a) to (d). Since the frame 400′ does not include the conductive copper post 201, the heat dissipation copper post 202′ may have a larger area to facilitate heat dissipation. Similar to frame 400, frame 400′ includes a first surface 402′ and a second surface 403′. The heat dissipation copper post 202′ is exposed to the first surface 402′ and wrapped in the second surface 403′.

Next, the first rewiring layer, the third dielectric layer, the second rewiring layer, the fourth dielectric layer and the third rewiring layer, are fabricated with reference to the aforementioned process in step (d)-step (h)-step (b′), as shown in FIG. 3B. Through step (b′), stepwise fan-out of the terminals of the device is achieved.

Then, referring to the aforementioned step (j), the fourth rewiring layer 901′ is fabricated to obtain a fan-out panel level packaging structure 1000′-step (c′), as shown in FIG. 3C. The fourth rewiring layer 901′ includes a heat dissipation copper surface covering substantially the entire first surface connecting the heat dissipation copper post and the back surface of the device, enabling large-area direct heat dissipation. Since there is no conductive copper post, the area of the heat dissipation copper post and the heat dissipation copper surface is larger, which is more helpful to heat dissipation.

Finally, the fan-out packaging structure 1000′ may be in conductive connection to a substrate or PCB board 1002′ using the third rewiring layer 703 to form a pad-step (d′), as shown in FIG. 3D. It should be noted that a double-sided on-package package cannot be realized because there is no conductive copper post.

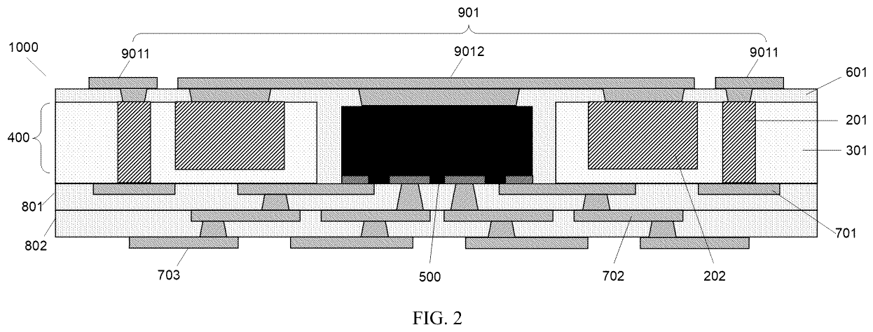

Based on similar inventive concepts, an embodiment of the present disclosure also provides a fan-out panel level packaging structure. FIG. 2 illustrates a schematic cross-sectional diagram of a fan-out panel level packaging structure 1000 provided by an embodiment of the present disclosure.

Specifically, fan-out panel level packaging structure 1000 includes a frame 400, a device 500, a first rewiring layer 701, a third dielectric layer 801, a second rewiring layer 702, a fourth dielectric layer 802, and a third rewiring layer 703. The frame 400 is provided with a device 500, and the second surface of the frame 400 is successively provided with a first rewiring layer 701, a third dielectric layer 801, a second rewiring layer 702, a fourth dielectric layer 802 and a third rewiring layer 703; the first rewiring layer 701 and the second rewiring layer 702 are connected to a first terminal and a second terminal of the device 500, respectively, the first rewiring layer 701 is connected to the second rewiring layer 702, and the second rewiring layer 702 is connected to the third rewiring layer 703. With such a structure, the first terminal and the second terminal of the device 500 are fanned out in stages, so that it is possible to realize rational wiring of fan-out of a highly dense I/O device terminal, and to reduce the wiring space in the horizontal direction.

In some embodiments, a second dielectric layer 601 and a fourth rewiring layer 901 are disposed on a first surface of the frame 400; the fourth rewiring layer 901 includes a functional loop terminal 9011 and a heat dissipation copper surface 9012; the heat dissipation copper surface 9012 is connected to the back surface of the device 500 and the heat dissipation copper post 202, and two ends of the conductive copper post 201 in the frame 400 are respectively connected to the functional loop terminal 9011 and the first rewiring layer 701. Using the heat dissipation copper surface 9012, a large area of heat dissipation can be achieved, and with the conductive copper post 201 and the functional loop terminal 9011, another device or package can be in conductive connection (as shown in FIG. 1K).

An embodiment of the present disclosure further provides another fan-out panel level packaging structure. FIG. 4 illustrates another schematic cross-sectional diagram of a fan-out panel level packaging structure 1000′ provided by an embodiment of the present disclosure.

Similar to the fan-out panel level packaging structure 1000, the fan-out panel level packaging structure 1000′ also achieves fractional fan-out of the device terminals using the first rewiring layer 701′, the second rewiring layer 70′2, and the third rewiring layer 703′. The fan-out panel level packaging structure 1000′ differs from the fan-out panel level packaging structure 1000 in that the frame does not contain a conductive copper post 201, and therefore the fourth rewiring layer 901′ includes a back surface of a connection device 500 and the heat dissipation copper surface of the heat dissipation copper post 202, but does not include a functional loop terminal.

The fan-out panel level packaging structure of the above-described embodiments has the advantageous effects of the corresponding method embodiments and will not be described in detail herein.

A person skilled in the art will appreciate that, the discussion of any embodiment mentioned above is merely exemplary and is not intended to imply that the scope of the disclosure, including the claims, is limited to these examples. Combinations of features in the above-mentioned embodiments, or between different embodiments, may also be made within the spirit of the present disclosure; the steps may be implemented in any order, and there may be many other variations of the different aspects of the embodiments of the present disclosure as described above, which are not provided in detail for clarity.

The disclosed embodiments are intended to embrace all such alternatives, modifications and variances which fall within the broad scope of the appended claims. Therefore, any omissions, modifications, equivalent substitutions, improvements, etc. made within the spirit and principles of the embodiments of the present disclosure shall be included within the scope of the present disclosure.

What is claimed is:

1. A method for manufacturing a fan-out panel level packaging structure, the method comprising:
(a) preparing a panel level frame having a first dielectric layer and a through-cavity surrounded by the first dielectric layer, wherein the frame comprises a first surface and a second surface, and a heat dissipation copper post extending through the first dielectric layer and exposed to the first surface;
(b) mounting a device in the through-cavity with a terminal face of the device flush with the second surface and the terminal face comprising a first terminal and a second terminal; forming a second dielectric layer, which covers the device, on the first surface;
(c) forming a first rewiring layer, which fans out the first terminal, on the second surface; and
(d) forming a third dielectric layer on the first rewiring layer, and forming a second rewiring layer, which fans out the second terminal, on the third dielectric layer, wherein the second rewiring layer is in conductive connection with the first rewiring layer.

2. The method according to claim 1, further comprising:
(f) windowing the second dielectric layer to expose the heat dissipation copper post and a back surface of the device; and
(g) forming a fourth rewiring layer comprising a heat dissipation copper surface on the second dielectric layer, wherein the heat dissipation copper surface is in conductive connection with the heat dissipation copper post and the back surface of the device.

3. The method according to claim 1, wherein the frame further comprises a conductive copper post, two end faces of the conductive copper post being exposed to the first surface and the second surface, respectively;
wherein the method further comprises:
(f) windowing the second dielectric layer to expose the conductive copper post, the heat dissipation copper post and a back surface of the device; and
(g) forming a fourth rewiring layer comprising a functional loop terminal and a heat dissipation copper surface on the second dielectric layer, wherein the functional loop terminal is in conductive connection with the conductive copper post and the heat dissipation copper surface is in conductive connection with the heat dissipation copper post and the back surface of the device.

4. The method according to claim 3, wherein the conductive copper post is further in conductive connection with the functional loop terminal and the first rewiring layer.

5. The method according to claim 1, wherein step (a) comprises sub-steps of:
(a1) preparing a panel level carrier plate, and forming the heat dissipation copper post and an annular sacrificial copper post on the carrier plate, wherein a height of the heat dissipation copper post is less than a height of the sacrificial copper post;
(a2) forming the first dielectric layer on the carrier plate so that the sacrificial copper post is exposed to the first dielectric layer;
(a3) removing the carrier plate; and
(a4) etching and removing the sacrificial copper post so that the first dielectric layer surrounded by the sacrificial copper post falls off to form the frame having the heat dissipation copper post and the through-cavity, wherein the frame comprises the first surface and the second surface, and the heat dissipation copper post is exposed to the first surface.

6. The method according to claim 3, wherein step (a) comprises sub-steps of:
(a1) preparing a panel level carrier plate, and forming the conductive copper post, the heat dissipation copper post and an annular sacrificial copper post on the carrier plate, wherein a height of the heat dissipation copper post is less than a height of the sacrificial copper post and the conductive copper post;
(a2) forming the first dielectric layer on the carrier plate so that the sacrificial copper post is exposed to the first dielectric layer;
(a3) removing the carrier plate; and
(a4) etching and removing the sacrificial copper post so that the first dielectric layer surrounded by the sacrificial copper post falls off to form the frame having the conductive copper post, the heat dissipation copper post and the through-cavity, wherein the frame comprises the first surface and the second surface, the heat dissipation copper post is exposed to the first surface, and the conductive copper post is exposed to the first surface and the second surface.

7. The method according to claim 5, wherein a height difference between the heat dissipation copper post and the sacrificial copper post is 20-50 μm.

8. The method according to claim 6, wherein the sacrificial copper post and the conductive copper post are flush with the second surface.

9. The method according to claim 1, wherein step (d) comprises sub-steps of:
(d1) windowing the third dielectric layer by means of exposure and development to expose the second terminal of the device and the first rewiring layer;
(d2) forming a third metal seed layer on a surface of the third dielectric layer;
(d3) applying a third photoresist layer on the third metal seed layer, and patterning the third photoresist layer to form a third feature pattern;
(d4) electroplating the third feature pattern to form a second rewiring layer fanning out the second terminal and being in conductive connection with the first rewiring layer; and
(d5) removing the third photoresist layer and etching the exposed third metal seed layer.

10. The method according to claim 1, further comprising:
(e) forming a fourth dielectric layer on the second rewiring layer, and fabricating a third rewiring layer on the fourth dielectric layer, wherein the third rewiring layer is in conductive connection with the second rewiring layer.

11. The method according to claim 2, wherein the heat dissipation copper post constitutes rest of the frame except the cavity and is separated from the cavity via the first dielectric layer; and the heat dissipation copper surface covers the second surface of the frame.

12. The method according to claim 3, wherein the heat dissipation copper post constitutes rest of the frame except the cavity and the conductive copper post and is separated from the cavity and the conductive copper post via the first dielectric layer; and
the heat dissipation copper surface covers the second surface except the functional loop terminal.

13. A fan-out panel level packaging structure, comprising a frame and a device embedded in the frame, wherein the frame comprises a heat dissipation copper post and a first dielectric layer for separating the heat dissipation copper post and the device, wherein the frame has a first surface and a second surface opposite to each other, and a first rewiring layer, a third dielectric layer and a second rewiring layer are successively provided on the second surface; and the first rewiring layer and the second rewiring layer are in conductive connection with and fan out a first terminal and a second terminal of the device, respectively, and the first rewiring layer is in conductive connection with the second rewiring layer.

14. The packaging structure according to claim 13, further comprising a fourth dielectric layer on the second rewiring layer and a third rewiring layer on the fourth dielectric layer, the third rewiring layer being in conductive connection with the second rewiring layer.

15. The packaging structure according to claim 13, further comprising a second dielectric layer provided on the first surface of the frame and a fourth rewiring layer on the second dielectric layer, wherein the fourth rewiring layer comprises a heat dissipation copper surface, the heat dissipation copper surface is in conductive connection with the heat dissipation copper post and a back surface of the device, and the heat dissipation copper surface covers the first surface.

16. The packaging structure according to claim 13, wherein the frame further comprises a conductive copper post, the conductive copper post being separated from the heat dissipation copper post via the first dielectric layer; a second dielectric layer provided on the first surface of the frame and a fourth rewiring layer on the second dielectric layer; the fourth rewiring layer comprising a functional loop terminal and a heat dissipation copper surface, wherein the heat dissipation copper surface is in conductive connection with the heat dissipation copper post and a back surface of the device, the heat dissipation copper surface covers the first surface except the functional loop terminal, and two ends of the conductive copper post are respectively in conductive connection with the functional loop terminal and the first rewiring layer.
